(19) United States
(12) Patent Application Publication
(10) Pub. No.: US 2026/0293762 A1
(43) Pub. Date: Sep. 24, 2026

(54) SEMICONDUCTOR DEVICE AND MANUFACTURING METHOD OF SEMICONDUCTOR DEVICE

(71) Applicant: Kioxia Corporation, Tokyo (JP)

(72) Inventor: Ryo MATSUOKA, Yokkaichi Mie (JP)

(21) Appl. No.: 19/318,189

(22) Filed: Sep. 3, 2025

(30) Foreign Application Priority Data
Mar. 19, 2025 (JP) 2025-044343

(51) Int. Cl. H01L 23/00; H01L 25/18

(52) U.S. Cl. CPC H10W 90/00; H10W 72/01908; H10W 72/01951; H10W 72/981; H10W 72/985; H10W 80/312; H10W 80/327; H10W 90/26; H10W 90/792

(57) ABSTRACT

According to one embodiment, a semiconductor device includes a first semiconductor element that has a first dummy pattern and a first active pattern and a second semiconductor element joined to the first semiconductor element. The second semiconductor element has a second dummy pattern facing the first dummy pattern. The first dummy pattern includes a first region. The second dummy pattern includes a second region. The first region and the second region face each other. The size of the first region is greater than the average area of pads included in the first active pattern. The pattern coverage rate of the first region is different from the pattern coverage rate of the second region.

### CROSS-REFERENCE TO RELATED APPLICATIONS

This application is based upon and claims the benefit of priority from Japanese Patent Application No. 2025-044343, filed Mar. 19, 2025, the entire contents of which are incorporated herein by reference.

### FIELD

Embodiments described herein relate generally to a semiconductor device and a manufacturing method of a semiconductor device.

### BACKGROUND

There are cases where a plurality of chips are stacked by joining the chips in a semiconductor package.

### BRIEF DESCRIPTION OF THE DRAWINGS

FIG. 1 is a schematic cross-sectional view of a semiconductor device in an embodiment.

FIG. 2 is a schematic diagram of a first dummy pattern and a second dummy pattern in an embodiment.

FIG. 3 is a schematic diagram of a first dummy pattern and a second dummy pattern in an embodiment.

FIG. 4 is a schematic diagram of a first dummy pattern and a second dummy pattern in an embodiment.

FIG. 5 is a schematic diagram of a first dummy pattern and a second dummy pattern in an embodiment.

FIG. 6 is a schematic diagram of a first dummy pattern and a second dummy pattern in an embodiment.

FIG. 7 is a schematic diagram of a first dummy pattern and a second dummy pattern in an embodiment.

FIG. 8 is a schematic diagram of a first dummy pattern and a second dummy pattern in an embodiment.

FIG. 9 is a schematic diagram of a first dummy pattern and a second dummy pattern in an embodiment.

FIG. 10 is a schematic diagram of a first dummy pattern and a second dummy pattern in an embodiment.

FIG. 11 is a schematic diagram of a first dummy pattern and a second dummy pattern in an embodiment.

FIG. 12 is a schematic cross-sectional view of a first semiconductor element of a portion of a first dummy pattern and a second semiconductor element of a portion of a second dummy pattern in an embodiment.

FIG. 13 is a schematic cross-sectional view of a first semiconductor element of the portion of a first dummy pattern and a second semiconductor element of the portion of a second dummy pattern in an embodiment.

FIG. 14 is a schematic cross-sectional view of a first semiconductor element of the portion of a first dummy pattern and a second semiconductor element of the portion of a second dummy pattern in an embodiment.

FIG. 15 is a schematic diagram of surfaces of a first semiconductor element and a second semiconductor element in an embodiment.

FIG. 16 is a flowchart of a manufacturing method of the semiconductor device in the embodiment.

FIGS. 17-21 are schematic diagrams depicting aspects of a manufacturing method of a semiconductor device according to an embodiment.

FIG. 22 is a schematic cross-sectional view of a semiconductor device in an embodiment.

FIG. 23 is a schematic cross-sectional view of a semiconductor device in an embodiment.

### DETAILED DESCRIPTION

A semiconductor device having improved reliability in the bonding between chips, and a manufacturing method for such a semiconductor device are provided.

In general, according to one embodiment, a semiconductor device includes a first semiconductor element that has a first dummy pattern and a first active pattern and a second semiconductor element that has a second dummy pattern facing the first dummy pattern. The first semiconductor element is joined to the second semiconductor element. The first dummy pattern includes a first region. The second dummy pattern includes a second region. The first region and the second region face each other when the semiconductor elements are joined. The size of the first region is greater than the average area of pads included in the first active pattern. The pattern coverage rate of the first region is different from the pattern coverage rate of the second region.

Hereinafter, certain example embodiments according to the present disclosure will be described with reference to the drawings. These example embodiments do not limit the present disclosure. It should be noted that the drawings are schematic or conceptual, and thus the depicted proportions, dimensions, and the like of each part are not necessarily identical to those in reality. In the description and the drawings, the same reference symbols are given to elements substantially similar to those already described in conjunction a preceding drawing, and additional description thereof may be omitted where appropriate.

### First Embodiment

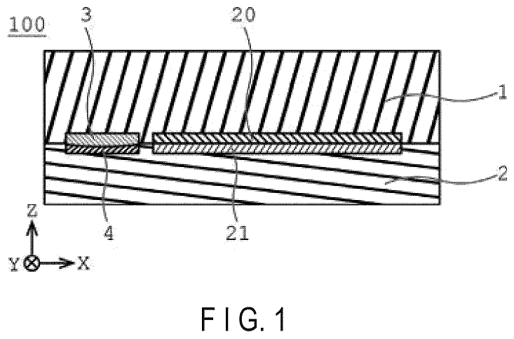

A first embodiment relates to a semiconductor device and a manufacturing method of the semiconductor device. FIG. 1 is a schematic cross-sectional view of a semiconductor device 100 in the first embodiment. The semiconductor device 100 includes a first semiconductor element 1 and a second semiconductor element 2. In the first semiconductor element 1 and the second semiconductor element 2, for example, an electrode provided on a surface of the first semiconductor element 1 facing the second semiconductor element 2 side is connected (bonded) to an electrode provided on a surface of the second semiconductor element 2 facing the first semiconductor element 1 side, without a solder bump or the like. The electrodes thus bonded may each be a metal such as copper (Cu) or the like. The first semiconductor element 1 is joined (bonded) to the second semiconductor element 2.

In FIG. 1, a surface of the first semiconductor element 1 in an X-Y plane and a surface of the second semiconductor element 2 in an X-Y plane are stacked on each other in the Z direction.

In this example, the first semiconductor element 1 and the second semiconductor element 2 have different circuit configurations. Since the first semiconductor element 1 and the second semiconductor element 2 are different types of elements, the joining of the first semiconductor element 1 and the second semiconductor element 2 is called hybrid joining.

Pads, terminals, or solder balls are provided on a surface on the opposite side of the joining surface side of the first semiconductor element 1 or the second semiconductor element 2, and can be electrically connected to an external passive element or active element.

The semiconductor device 100 is, for example, a storage device or an arithmetic device. An arithmetic device may include a storage device.

The semiconductor device 100 is preferably a storage device in this example. The type of storage device of the semiconductor device 100 is not limited, but is, for example, a nonvolatile memory chip or a volatile memory chip. As a nonvolatile memory chip, for example, a NAND flash memory chip, a magnetoresistance memory chip, a resistance memory chip, or a phase change memory chip are options. As a volatile memory chip, a DRAM (dynamic random access memory) including a DDR (double data rate) memory, an HBM (high bandwidth memory), and a GDDR (graphics double data rate) memory are options.

The type of arithmetic device of the semiconductor device 100 is not limited, but is, for example, a CPU (central processing unit), a GPU (graphic processing unit), an FPGA (field-programmable gate array), or the like.

The first semiconductor element 1 has a first dummy pattern 3. The first dummy pattern 3 is not electrically connected to a first circuit element included in the first semiconductor element 1. The first circuit element includes a transistor or the like. The first dummy pattern 3 includes, for example, a pad formed from a conductive material such as Cu or aluminum (Al). The first circuit element is electrically connected to a first active pattern 20. The first semiconductor element 1 includes, for example, a first semiconductor layer that includes the first circuit element, and a first wiring layer that includes the first dummy pattern 3 and the first active pattern 20.

The second semiconductor element 2 has a second dummy pattern 4. The second dummy pattern 4 is not electrically connected to a second circuit element included in the second semiconductor element 2. The second circuit element includes a transistor or the like. The second dummy pattern 4 includes, for example, a pad formed from a conductive material such as Cu or Al. A part of the second dummy pattern 4 is preferably electrically connected to the first dummy pattern 3. The second circuit element is electrically connected to a second active pattern 21. The second semiconductor element 2 includes, for example, a second semiconductor layer that includes the second circuit element, and a second wiring layer that includes the second dummy pattern 4 and the second active pattern 21. In the semiconductor device 100, the first wiring layer of the first semiconductor element 1 and the second wiring layer of the second semiconductor element 2 are connected to face each other.

The first dummy pattern 3 faces the second dummy pattern 4.

A plurality of pads are included in the region of the first active pattern 20. The plurality of pads included in the first active pattern 20 are, for example, conductive pads such as Cu or Al. The pads included in the first active pattern 20 are electrically connected to pads included in the second active pattern 21. The first active pattern 20 is not electrically connected to the first dummy pattern 3 and the second dummy pattern 4.

The plurality of pads are included in the region of the second active pattern 21. The plurality of pads included in the second active pattern 21 are, for example, conductive pads such as Cu or Al. The second active pattern 21 is not electrically connected to the first dummy pattern 3 and the second dummy pattern 4.

The size of the region of the first dummy pattern 3 is preferably substantially the same as the size of the region of the second dummy pattern 4. The size of the region of the first dummy pattern 3 is preferably between 90% and 110% (range end points inclusive) of the size of the region of the second dummy pattern 4, more preferably between 95% and 105% (range end points inclusive), and even more preferably between 98% and 102% (range end points inclusive).

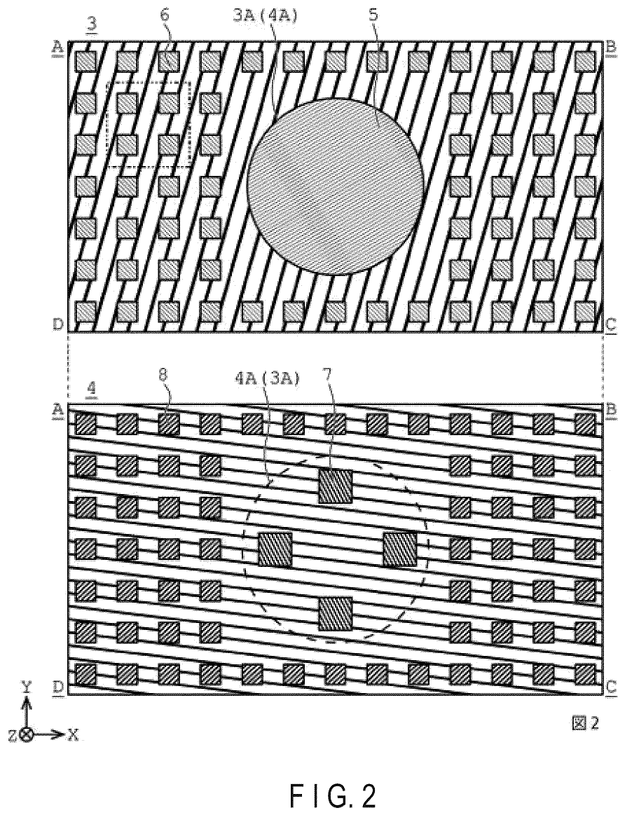

FIG. 2 illustrates a schematic diagram of the first dummy pattern 3 and the second dummy pattern 4. The first dummy pattern 3 includes a first region 3A as a mark region. The second dummy pattern 4 includes a second region 4A as a mark region. The broken line of the second dummy pattern 4 in FIG. 2 indicates the outer circumference of the second region 4A. In the schematic diagram of FIG. 2, the first region 3A and the second region 4A have a common outer circumference. The first region 3A and the second region 4A face each other. Underlined A, B, C, and D in FIG. 2 represent the positions that are common to the first dummy pattern 3 and the second dummy pattern 4.

The schematic diagram of FIG. 2 illustrates the position of the second region 4A of the second dummy pattern 4 that overlaps the first dummy pattern 3. In addition, the schematic diagram of FIG. 2 illustrates the position of the first region 3A of the first dummy pattern 3 that overlaps the second dummy pattern 4. That is, the position of the second region 4A facing the first region 3A is illustrated in the schematic diagram of the first dummy pattern 3. In addition, the position of the first region 3A facing the second region 4A is illustrated in the schematic diagram of the second dummy pattern 4.

A circular pad 5 is provided in the first region 3A of the schematic diagram of FIG. 2, and in the region other than the first region 3A, a regular dummy pattern region (for example, a non-mark region) where pads 6 having the same size are regularly arranged is also included. A pattern different from the regular dummy pattern region is provided as the pattern in the first region 3A is. The operation of the first semiconductor element 1 is not affected even if the first dummy pattern 3 is not present, but if the first dummy pattern 3 is not present, the first dummy pattern 3 may become a large convex surface and may become a three-dimensional obstacle during bonding, and thus it is preferable that the first dummy pattern 3 is present, and it is preferable to use the first dummy pattern 3 as a reference position for positioning at the time of forming the wiring layer of the first semiconductor element 1.

The size of the first region 3A is preferably larger than the average area of the pads included in the first active pattern 20.

The size of the first region 3A is preferably larger than the average area of the pads except for the mark region included in the first dummy pattern 3.

The size of the first region 3A is preferably larger than the maximum area of the pads included in the first active pattern 20.

The shape of the pad 5 in the first region 3A can be one or more shapes selected from the group consisting of a circle, an oval, a square, a polygon, and a cross, or a shape similar to these. There are one or more pads 5 in the first region 3A, and each pad may be arranged spaced apart or/and in contact with each other. The pad 5 in the first region 3A may be a solid film or arranged at a high density.

When the shape of the pad 5 in the first region 3A is a rounded shape such as a circle, an oval, or a polygon with rounded corners, a part of the outer circumference of the pad 5 may be joined to pads 7 of the second region 4A, or pads included in a region directly adjacent to the second region 4A.

The first region 3A is present at any position of the first dummy pattern 3.

A pattern formed by the plurality of pads 7 is provided in the second region 4A of the schematic diagram of FIG. 2, and in the region other than the second region 4A, a regular dummy pattern region (for example, a non-mark region) where pads 8 having the same size are regularly arranged is also included. A pattern different from the regular dummy pattern region is provided as the pattern in the second region 4A.

The shape of the pad 7 in the second region 4A can be one or more selected from the group consisting of a circle, an oval, a square, a polygon, and a cross, or a shape incorporating these. There are one or more pads 7 in the second region 4A, and each pad is arranged spaced apart or/and in contact with each other. The pads 7 are not arranged in the second region 4A, or the pads 7 are arranged at a low density compared with the first region 3A.

The second region 4A can be present at any position of the second dummy pattern 4.

A mark region is a region in which an irregular pad pattern is provided in contrast to a regular dummy pattern region. A pattern of pads that have the same shape (or substantially the same shape) and that are at regular intervals (or at substantially regular intervals) is provided in the regular dummy pattern region. The boundary of a region (for example, the first region 3A, the second region 4A) in a mark region is a boundary that divides the regions based on the features of a pad pattern therein. With respect to a region with a high pattern coverage rate (percentage) as a reference, a portion facing the region with the high pattern coverage rate can be set as a paired region, for example, the second region 4A for the first region 3A. The mark region can be divided into a plurality of regions, based on features including the shape, density, and the like of a pattern.

The pattern coverage rate of the first region 3A is preferably different from the pattern coverage rate of the second region 4A. A pattern coverage rate is an area ratio of the pattern formed on a surface of the first semiconductor element 1 or the second semiconductor element 2 by a conductive material such as Cu. In general, the pattern coverage rate is not evaluated in a minute (small) region, but rather the pattern coverage rate can be obtained on the basis of, for example, a larger region (e.g., the square region surrounded by a dashed double-dotted line in FIG. 2) that includes two pads in a horizontal direction and two pads in a vertical direction and that is included in the regular dummy pattern region, and the average value thereof can be used as the pattern coverage rate. In addition, the first dummy pattern 3 and the second dummy pattern 4 can be divided into mark regions and non-mark regions the pattern coverage rate of each region can be obtained separately. For example, the edge of a pad can be detected, then the regularity of the shape, arrangement, and density of a pattern may be evaluated on the basis of the detected edge(s), and division into a plurality of regions can be performed.

There may be regions in which a pad is not present at all such as in the outer circumference of the first region 3A and the second region 4A of the schematic diagram of FIG. 2. Since the regions where a pad is not present are common in the first dummy pattern 3 and the second dummy pattern 4, and the pattern coverage rate in such regions is typically zero, these regions where no pad is present are treated as regular dummy pattern regions of the first dummy pattern 3 and the second dummy pattern 4.

The pattern coverage rate of the first region 3A is preferably higher than the pattern coverage rate of the second region 4A. The pattern coverage rate of the second region 4A is preferably between 0% and 80% (range end points inclusive) of the pattern coverage rate of the first region 3A, more preferably between 0% and 50% (range end points inclusive) of the pattern coverage rate of the first region 3A, and even more preferably between 0% and 20% (range end points inclusive) of the pattern coverage rate of the first region 3A.

The pattern coverage rate of the first region 3A is preferably higher than the pattern coverage rate of the entire first dummy pattern 3. The pattern coverage rate of the first region 3A is preferably 120% or more of the pattern coverage rate of the entire first dummy pattern 3, more preferably 150% or more of the pattern coverage rate of the entire first dummy pattern 3, and even more preferably 200% or more of the pattern coverage rate of the entire first dummy pattern 3.

The pattern coverage rate of second region 4A is preferably different from the pattern coverage rate of the entire second dummy pattern 4. The pattern coverage rate of the second region 4A is preferably lower than the pattern coverage rate of the entire second dummy pattern 4. The pattern coverage rate of the second region 4A is preferably 80% or less of the pattern coverage rate of the entire second dummy pattern 4, more preferably 50% or less of the pattern coverage rate of the entire second dummy pattern 4, and even more preferably 20% or less of the pattern coverage rates of the entire second dummy pattern 4.

A surface of the first region 3A with a high pattern coverage rate is likely to be chipped or damaged when CMP (chemical mechanical polishing) is performed on the surface of the first semiconductor element 1. The first region 3A is preferably a concave surface. The first region 3A is preferably a concave surface with respect to the surface of the first active pattern 20.

A surface of the second region 4A with a low pattern coverage rate is less likely to be chipped or damaged when CMP is performed on the surface of the second semiconductor element 2. It becomes a convex surface in processing. The second region 4A is preferably a convex surface. The second region 4A is preferably a convex surface with respect to the surface of the second active pattern 21.

The first dummy pattern 3 is, for example, a mark that indicates a reference position to be used when forming a wiring layer on the surface of the first semiconductor element 1. The second dummy pattern 4 is a mark that indicates a reference position to be used when forming a wiring layer of the surface of the second semiconductor element 2. Although a mark may be formed by a large pad in many cases, a large pad is typically more likely to be polished faster by CMP than silicon dioxide (SiO₂), which is typically the insulating film surrounding such a pad. As such, the large pad is more likely to be a concave surface after CMP. When both opposing surfaces to be joined are concave surfaces, a void is likely to be formed between the bonding surfaces. Conversely, when both opposing surfaces are convex surfaces, it becomes difficult to fully bond the opposing surfaces together. Therefore, by making the mark for the wiring layer on the surface of the first semiconductor element 1 into a concave surface, and making the mark for the wiring layer on the surface of the second semiconductor element 2 into a convex surface, the convex surface facing the concave surface helps fill the gap of the concave surface, and thus they can function as the marks while the occurrence of voids at the bonding surface can be reduced.

The volume of the gap of the concave surface of the first region 3A is preferably greater than the volume of the protruding portion of the convex surface of the second region 4A. The volume of the gap of the concave surface of first region 3A is preferably between 50% and 80% (range end points inclusive) of the volume of the protruding portion of the convex surface of the second region 4A, more preferably between 80% and 90% (range end points inclusive), and even more preferably between 90% and 100% (range end points inclusive).

In the schematic diagram of FIG. 2, the pattern of each mark is formed in one region, but marks may be formed by a plurality of regions. When two or more regions with a high pattern coverage rate are included in the first semiconductor element 1, and when one or more regions with a high pattern coverage rate are included in the second semiconductor element 2, each of the regions with a high pattern coverage rate preferably faces a region with a low pattern coverage rate.

The pattern coverage rate of the regular dummy pattern region of the first dummy pattern 3 is preferably between 0% and 50% (range end points inclusive), more preferably between 10% and 40% (range end points inclusive), and even more preferably between 20% and 30% (range end points inclusive). The regular dummy pattern region of the first dummy pattern 3 preferably has a higher flatness than the first region 3A.

The pattern coverage rate of the regular dummy pattern region of the second dummy pattern 4 is preferably between 0% and 50% (range end points inclusive), more preferably between 10% and 40% (range end points inclusive), and even more preferably between 20% and 30% (range end points inclusive). The regular dummy pattern region of the second dummy pattern 4 preferably has a higher flatness than the second region 4A.

The first region 3A and the second region 4A preferably have different pattern shapes, and the pattern shape in the first region 3A preferably has a pattern shape that is not similar to that in the second region 4A.

The pattern of the first region 3A illustrated in the schematic diagram of FIG. 2 is formed by one circular pad, and the pattern of the second region 4A is formed by a plurality of rectangular pads.

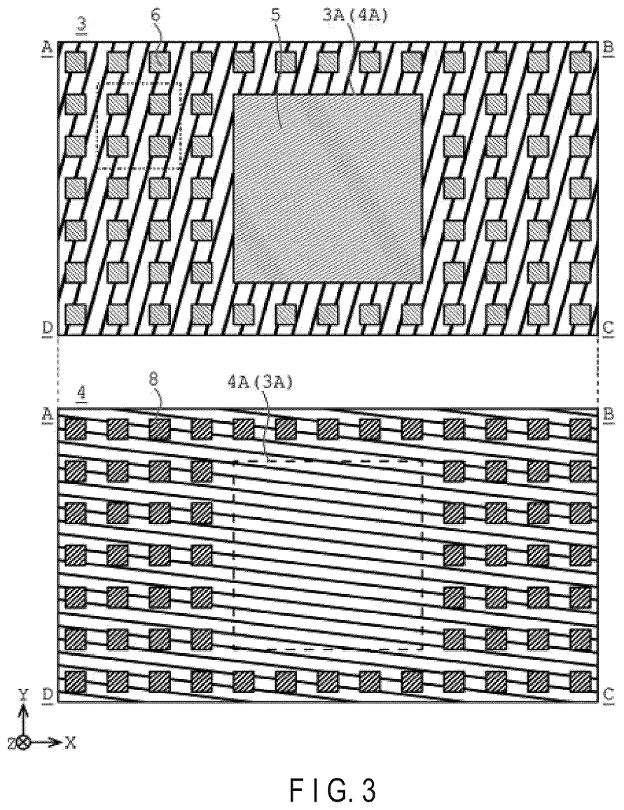

The variations of the first dummy pattern 3 and the second dummy pattern 4 are illustrated in the schematic diagrams of FIG. 3 to FIG. 11. The schematic diagrams of FIG. 3 to FIG. 11 can be considered modifications of the schematic diagram of FIG. 2.

In FIG. 3, the pad 5, which is a rectangular solid film, is provided in the entire first region 3A of the first dummy pattern 3, but the pad 7 is not provided in the second region 4A of the second dummy pattern 4. The first region 3A has a high pattern coverage rate and faces the second region 4A with a low pattern coverage rate. FIG. 3 is an example in which the difference between the pattern coverage rate of the first region 3A and the pattern coverage rate of the second region 4A is large.

When the pad 5 in the first region 3A is a polygon, two or more locations including a corner of the pad 5, preferably three or more locations including a corner of the pad 5, more preferably four or more locations including a corner of the pad 5 may be joined to the pads 7 included in the second region 4A or pads included in a region directly adjacent to the second region 4A.

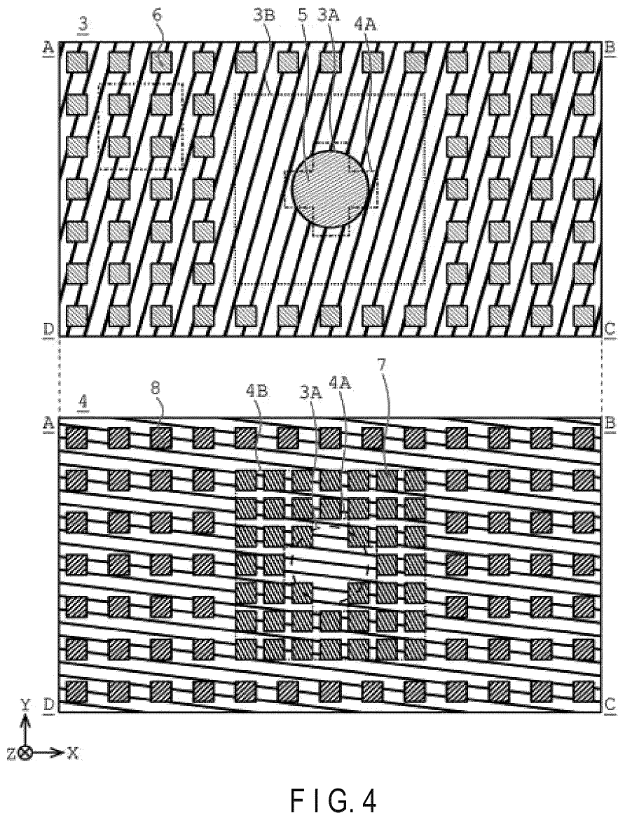

In FIG. 4, a first region 3A with a high pattern coverage rate and a third region 3B with a low pattern coverage rate on the outer side of the first region 3A are included in the first dummy pattern 3 of the first semiconductor element 1. The pad 5, which is a circular solid film, is provided in the first region 3A. The third region 3B is a region in which a pad is not provided. A second region 4A with a low pattern coverage rate and a fourth region 4B with a high pattern coverage rate on the outer side of the second region 4A are included in the second dummy pattern 4 of the second semiconductor element 2. The second region 4A is a region in which a pad is not provided. The fourth region 4B is a region with a high pattern coverage rate in which the pads 7 are arranged at a high density. Some of the pads 7 or parts of the pads in the second dummy pattern 4 may face and be joined to the pad 5 in the first region 3A.

It should be noted that the third region 3B may be a region having a higher pattern coverage rate than the first region 3A, and the fourth region 4B may be a region having a lower pattern coverage rate than the second region 4A.

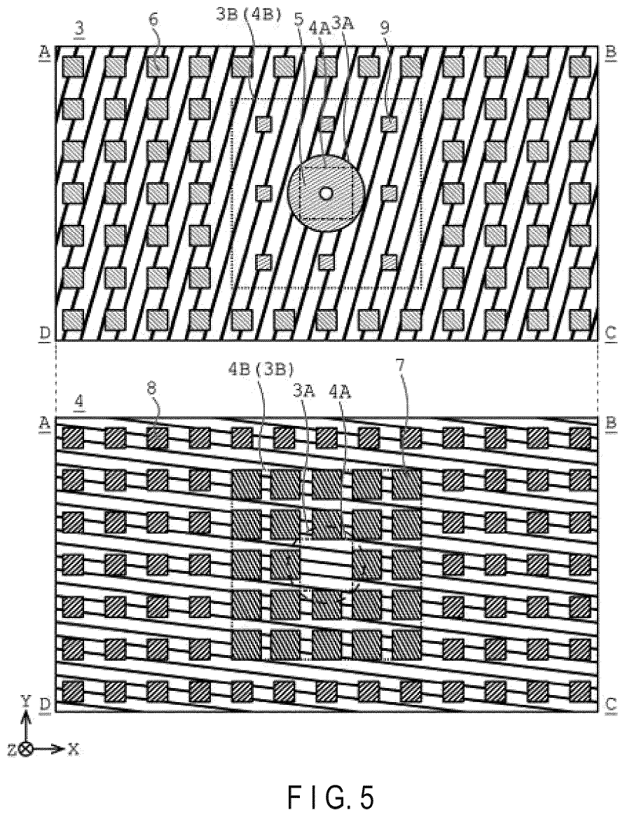

In FIG. 5, the first region 3A with a high pattern coverage rate and the third region 3B with a low pattern coverage rate on the outer side of the first region 3A are included in the first dummy pattern 3 of the first semiconductor element 1. The pad 5, which is a donut-shaped solid film, is provided in the first region 3A. The third region 3B is a region in which small pads 9 are provided at a low density, and the pattern coverage rate of the third region 3B is lower than the pattern coverage rate of the first region 3A, and is lower than the pattern coverage rate of the fourth region 4B. The second region 4A with a low pattern coverage rate and the fourth region 4B with a high pattern coverage rate on the outer side of the second region 4A are included in the second dummy pattern 4 of the second semiconductor element 2. The second region 4A is a region in which a pad is not provided. The fourth region 4B is a region with a high pattern coverage rate in which large pads 7 are arranged at a high density. Some of the pads 7 in the second dummy pattern 4 may face and be joined to the pad 5 in the first region 3A and the pads 9 in the third region 3B.

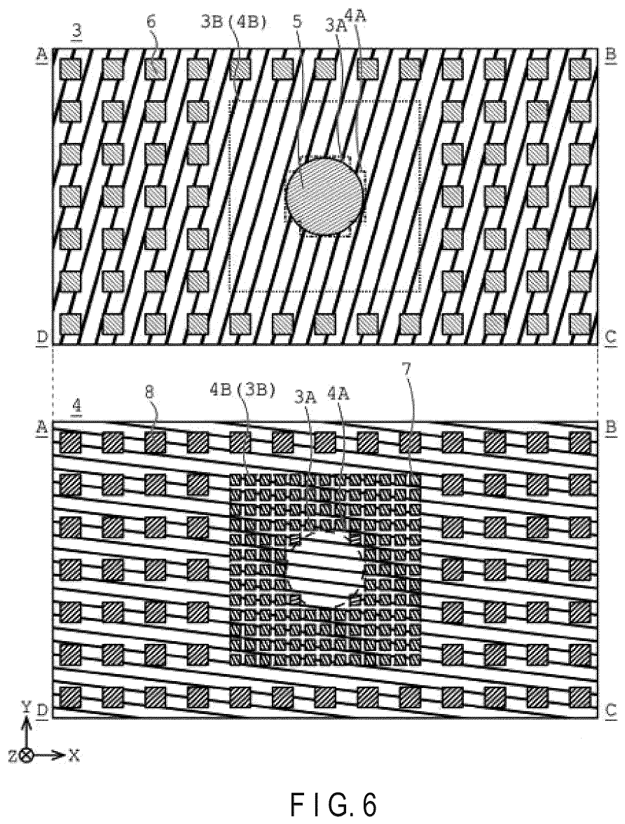

In FIG. 6, the first region 3A with a high pattern coverage rate and the third region 3B with a low pattern coverage rate on the outer side of the first region 3A are included in the first dummy pattern 3 of the first semiconductor element 1. The pad 5, which is a circular solid film, is provided in the first region 3A. The third region 3B is a region in which a pad is not provided. The second region 4A with a low pattern coverage rate and the fourth region 4B with a high pattern coverage rate on the outer side of the second region 4A are included in the second dummy pattern 4 of the second semiconductor element 2. The second region 4A is a region in which a pad is not provided. The fourth region 4B is a region with a high pattern coverage rate in which small pads 7 are arranged at a high density. Some of the pads 7 in the second dummy pattern 4 may face and be joined to the pad 5 in the first region 3A.

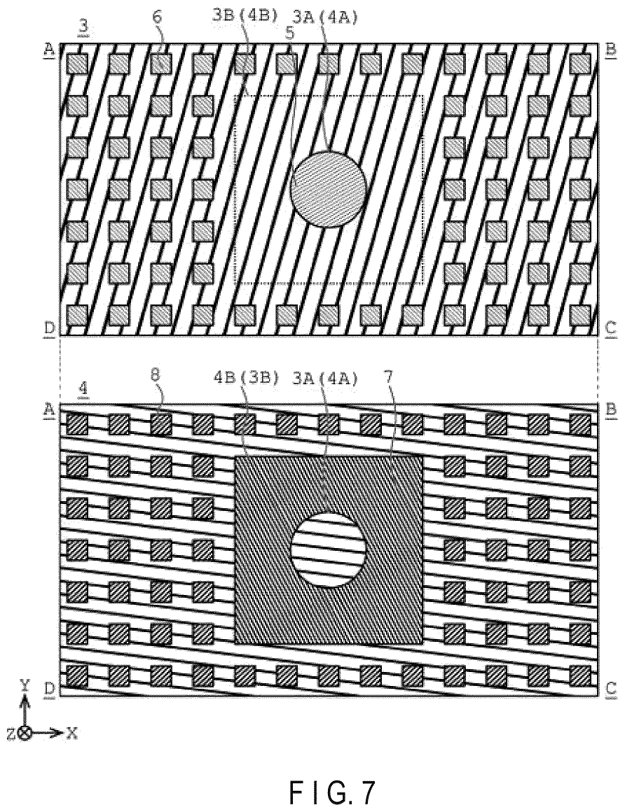

In FIG. 7, the first region 3A with a high pattern coverage rate and the third region 3B with a low pattern coverage rate on the outer side of the first region 3A are included in the first dummy pattern 3 of the first semiconductor element 1. The pad 5, which is a circular solid film, is provided in the first region 3A. The third region 3B is a region in which a pad is not provided. The second region 4A with a low pattern coverage rate and the fourth region 4B with a high pattern coverage rate on the outer side of the second region 4A are included in the second dummy pattern 4 of the second semiconductor element 2. The second region 4A is a region in which a pad is not provided. The fourth region 4B is a region with a high pattern coverage rate, the region being a solid film. A part of the pad 7 in the second dummy pattern 4 may face and be joined to the pad 5 in the first region 3A. The mark region of the first dummy pattern 3 has a pattern that is the inverse of the pattern in the mark region of the second dummy pattern 4.

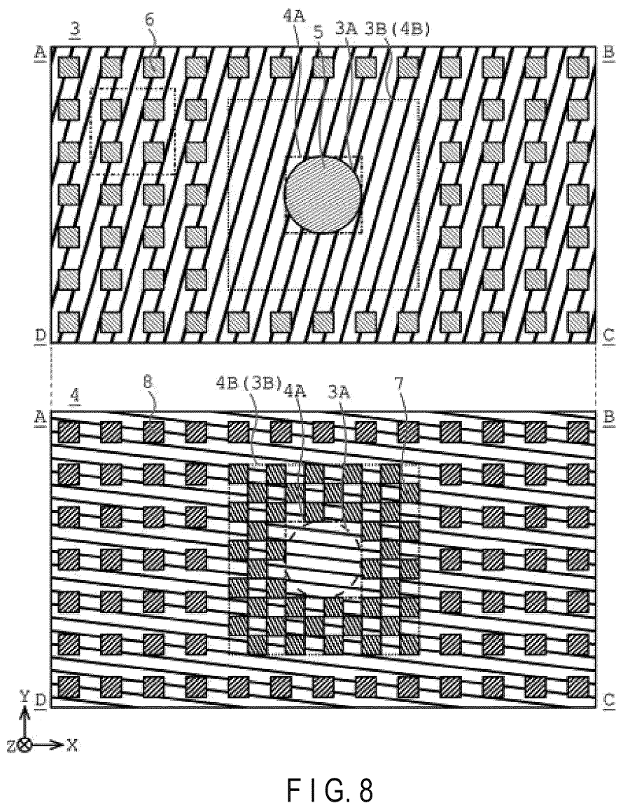

In FIG. 8, the first region 3A with a high pattern coverage rate and the third region 3B with a low pattern coverage rate on the outer side in the first region 3A are included in the first dummy pattern 3 of the first semiconductor element 1. The pad 5, which is a circular solid film, is provided in the first region 3A. The third region 3B is a region in which a pad is not provided. The second region 4A with a low pattern coverage rate and the fourth region 4B with a high pattern coverage rate on the outer side of the second region 4A are included in the second dummy pattern 4 of the second semiconductor element 2. The second region 4A is a region in which a pad is not provided. The fourth region 4B is a region with a high pattern coverage rate in which pads 7 are arranged in a checkerboard pattern. Some of the pads 7 in the second dummy pattern 4 may face and be joined to the pad 5 in the first region 3A.

When the pattern coverage rate of the third region 3B is low, the pattern coverage rate and the like are similar to the pattern coverage rate and the like of the second region 4A. When another dummy pattern that has a low pattern coverage rate and that is not electrically connected to the first circuit element and/or the second circuit element is included in the first dummy pattern 3 or/and the second dummy pattern 4, the coverage rate, size, relative size relationship with a facing region with a high pattern coverage rate, pad shape, surface unevenness, and the like of the dummy pattern with a low pattern coverage rate are similar to the pattern coverage rate, size, relative size relationship with a facing region with a high pattern coverage rate, pad shape, surface unevenness, and the like of the second region 4A.

When the pattern coverage rate of the fourth region 4B is high, the pattern coverage rate and the like are similar to the pattern coverage rate and the like of the first region 3A. When another dummy pattern that has a high pattern coverage rate and that is not electrically connected to the first circuit element and/or the second circuit element is included in the first dummy pattern 3 or/and the second dummy pattern 4, the coverage rate, size, relative size relationship with a facing region with a low pattern coverage rate, pad shape, surface unevenness, and the like of the dummy pattern with a high pattern coverage rate are similar to the pattern coverage rate, size, relative size relationship with a facing region with a low pattern coverage rate, pad shape, surface unevenness, and the like of the first region 3A.

When the first region 3A, the second region 4A, the third region 3B, and the fourth region 4B are included, in the first dummy pattern 3 of the first semiconductor element 1, the first region 3A has a concave surface and the third region 3B surrounding the concave surface has a convex surface. That is, the surface of the first dummy pattern 3 has the concave surface and the convex surface that surrounds and is continuous with the concave surface. In addition, in the second dummy pattern 4 of the second semiconductor element 2, the second region 4A is a convex surface, and the fourth region 4B surrounding the convex surface is a concave surface. That is, the surface of the second dummy pattern 4 has the convex surface and the concave surface that surrounds and is continuous with the convex surface. Also in this case, the convex surface and the concave surface face each other, and the convex surface enters the concave surface. Similar concave surface or convex surface may further be present in the outer circumference of the third region 3B and the fourth region 4B, respectively.

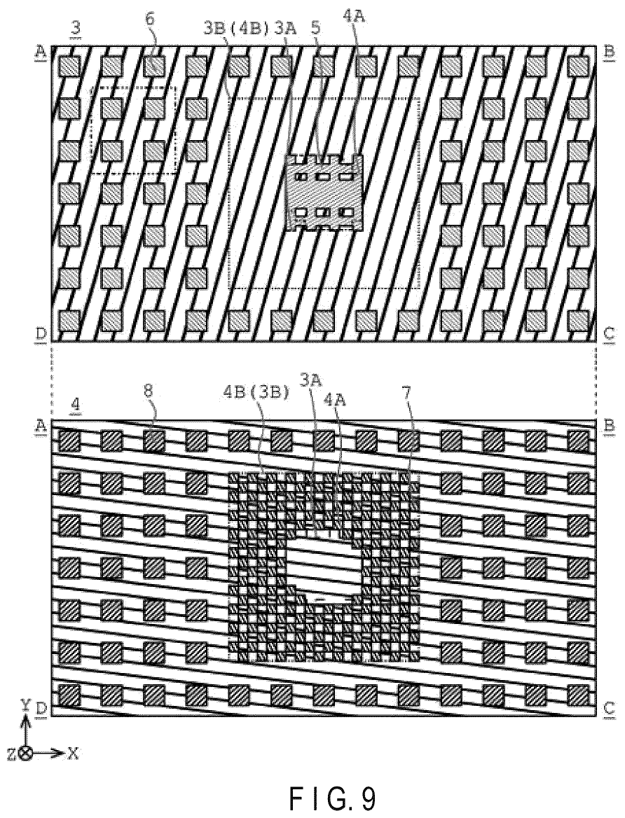

In FIG. 9, the first region 3A with a high pattern coverage rate and the third region 3B with a low pattern coverage rate on the outer side of the first region 3A are included in the first dummy pattern 3 of the first semiconductor element 1. The pad 5, which is a solid film with no particular shape, is provided in the first region 3A. The third region 3B is a region in which a pad is not provided. The second region 4A with a low pattern coverage rate and the fourth region 4B with a high pattern coverage rate on the outer side of the second region 4A are included in the second dummy pattern 4 of the second semiconductor element 2. The second region 4A is a region in which a pad is not provided. The fourth region 4B is a region with a high pattern coverage rate in which small pads 7 are arranged in a checkerboard pattern. Some of the pads 7 in the second dummy pattern 4 may face and be joined to the pad 5 in the first region 3A.

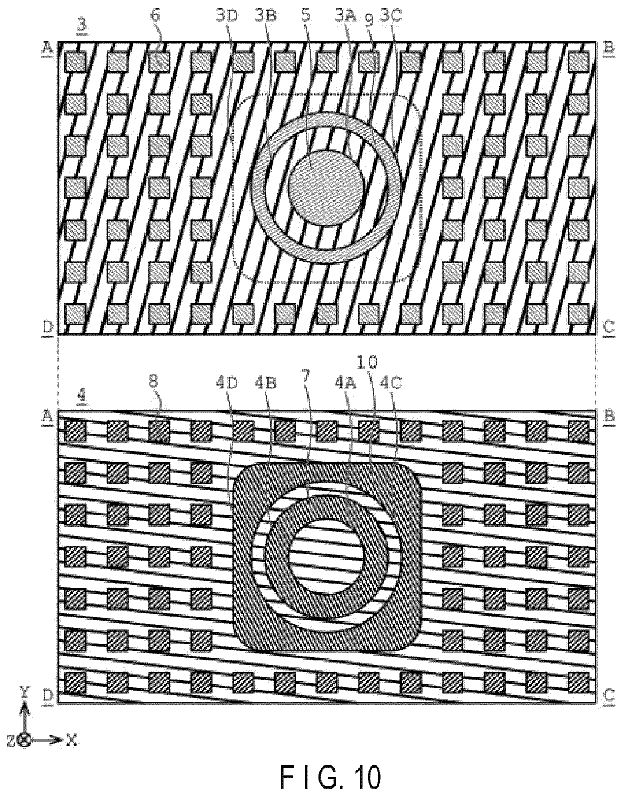

In FIG. 10, the first region 3A with a high pattern coverage rate, the third region 3B with a low pattern coverage rate on the outer side of the first region 3A, a fifth region 3C with a high pattern coverage rate on the outer side of the third region 3B, and a seventh region 3D with a low pattern coverage rate on the outer side of the fifth region 3C are included in the first dummy pattern 3 of the first semiconductor element 1. The pad 5, which is a circular solid film, is provided in the first region 3A. The third region 3B is a region in which a pad is not provided. The fifth region 3C is a region in which the pad 9 having a donut shape is provided. The seventh region 3D is a region in which a pad is not provided. The second region 4A with a low pattern coverage rate, the fourth region 4B with a high pattern coverage rate on the outer side of the second region 4A, a sixth region 4C with a low pattern coverage rate, and an eighth region 4D with a high pattern coverage rate are included in the second dummy pattern 4 of the second semiconductor element 2. The second region 4A is a region in which a pad is not provided. The fourth region 4B is a region with a high pattern coverage rate in which the pad 7 having a donut shape is provided. The sixth region 4C is a region in which a pad is not provided. The eighth region 4D is a region in which a pad 10 having a distorted donut shape is provided. The first region 3A and the second region 4A face each other. The third region 3B and the fourth region 4B face each other. The fifth region 3C and the sixth region 4C face each other. The seventh region 3D and the eighth region 4D face each other.

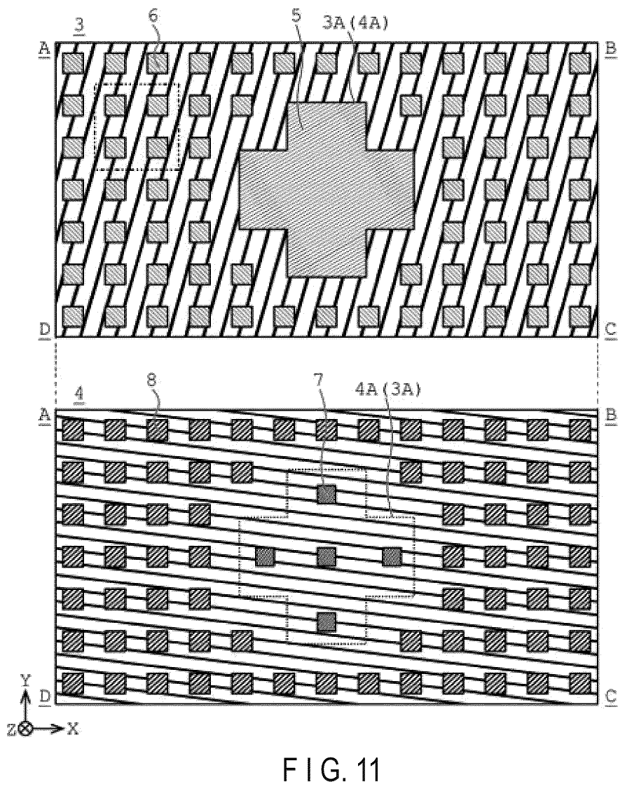

In FIG. 11, the first region 3A with a high pattern coverage rate and the third region 3B with a low pattern coverage rate on the outer side of the first region 3A are included in the first dummy pattern 3 of the first semiconductor element 1. The pad 5, which is a cross-shaped solid film, is provided in the first region 3A. The third region 3B is a region in which a pad is not provided. The second region 4A with a low pattern coverage rate and the fourth region 4B with a high pattern coverage rate on the outer side of the second region 4A are included in the second dummy pattern 4 of the second semiconductor element 2. The second region 4A is a region with a low pattern coverage rate in which pads 7 are provided. Some of the pads 7 in the second dummy pattern 4 may face and be joined to the pad 5 in the first region 3A.

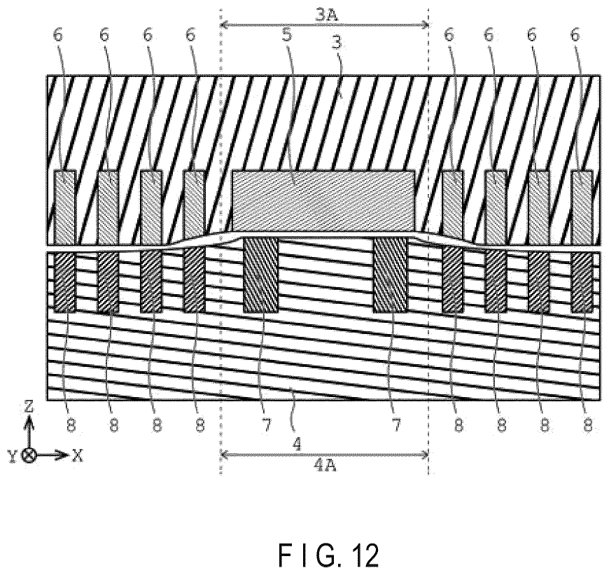

Next, a description will be given of a cross section including a surface in which the first dummy pattern 3 and the second dummy pattern 4 face each other. FIG. 12 illustrates a schematic cross-sectional view of the first semiconductor element 1 of a portion of the first dummy pattern 3 and the second semiconductor element 2 of a portion of the second dummy pattern 4. Since the first region 3A of the first dummy pattern 3 has a high pattern coverage rate, the first region 3A is a concave surface. The regular dummy pattern region of the first dummy pattern 3 is a flat surface with respect to the concave surface. Since the second region 4A of the second dummy pattern 4 has a low pattern coverage rate, the second region 4A is a convex surface. The regular pattern region of the second dummy pattern 4 is a flat surface with respect to the convex surface.

From a viewpoint of permitting the convex surface to enter the gap of the concave surface to prevent inhibition of the joining of bonding surfaces, when a first insulating film 11 and a second insulating film 12 are included in the semiconductor device 100, the area of the first region 3A is preferably between 150% and 200% (range end points inclusive) of the area of the second region 4A, more preferably between 120% and 150% (range end points inclusive) of the area of the second region 4A, and more preferably between 100% and 120% (range end points inclusive) of the area of the second region 4A.

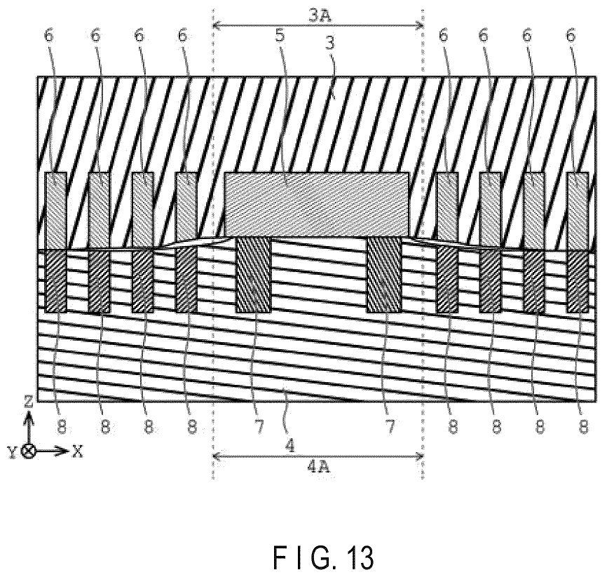

In the schematic diagram of the FIG. 12, the surface of the first dummy pattern 3 and the surface of the second dummy pattern 4 that face each other are separated, and the convex surface of the second region 4A enters the concave surface of the first region 3A. The surface of the first dummy pattern 3 and the surface of the second dummy pattern 4 may be in contact with each other, as illustrated in the schematic diagram of the first semiconductor element 1 of a portion of the first dummy pattern 3 and the second semiconductor element 2 of a portion of the second dummy pattern 4 in FIG. 13.

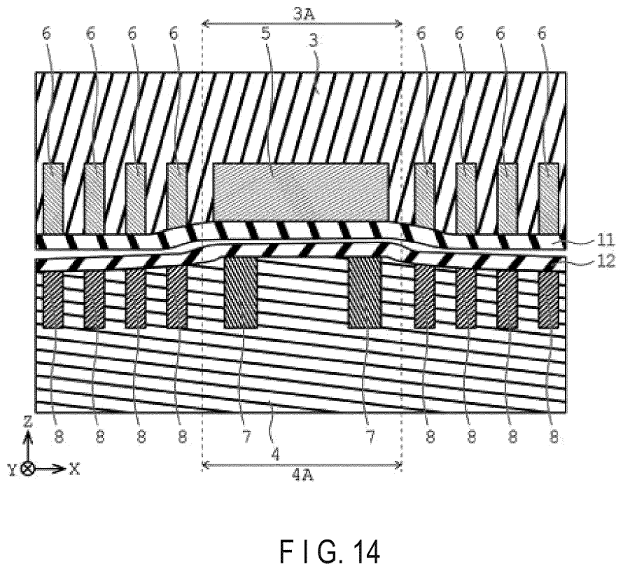

In addition, as illustrated in the schematic diagram of the first semiconductor element 1 of a portion of the first dummy pattern 3 and the second semiconductor element 2 of a portion of the second dummy pattern 4 in FIG. 14, the first insulating film 11 may be provided on the surface of the first semiconductor element 1 including the surface of the first dummy pattern 3, and the second insulating film 12 may be provided on the surface of the second semiconductor element 2 including the surface of the second dummy pattern 4. When the first insulating film 11 is provided on the surface in which the first dummy pattern 3 is provided, the first dummy pattern 3 is not provided in the outermost surface of the first semiconductor element 1. When the second insulating film 12 is provided on the surface in which the second dummy pattern 4 is provided, the second dummy pattern 4 is not provided in the outermost surface of the second semiconductor element 2.

A concave surface corresponding to the first region 3A is present in the first insulating film 11 on the first dummy pattern 3, and a convex surface corresponding to the second region 4A is present in the second insulating film 12 on the second dummy pattern 4. In addition, since the convex surface of the second insulating film 12 facing the concave surface enters the gap of the concave surface of the first insulating film 11, the occurrence of a void between joining surfaces can be suppressed.

Alignment marks or the like may be provided on the surfaces of the first insulating film 11 and the second insulating film 12. The alignment marks are preferably smaller than, for example, the pattern areas of the first dummy pattern 3 and the second dummy pattern 4. These alignment marks include, for example, a pair of nested marks that are not included in the first dummy pattern 3 and the second dummy pattern 4 in the embodiment.

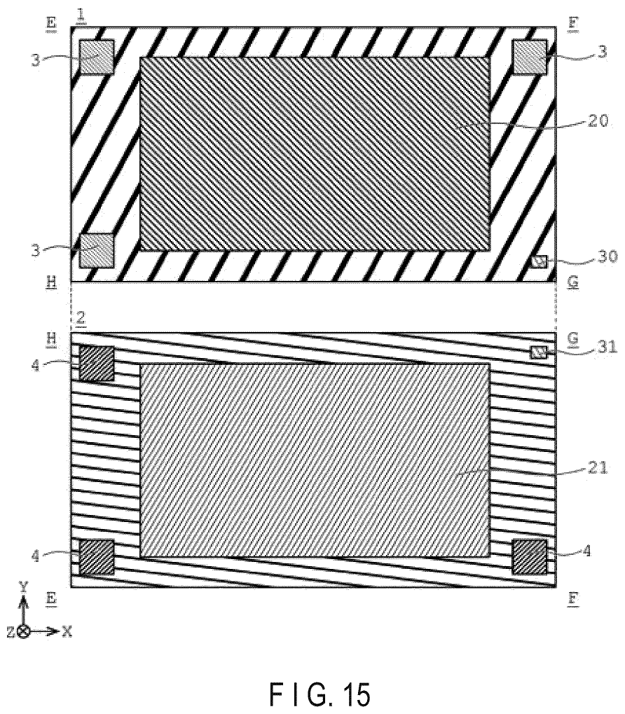

Next, referring to the schematic diagram of the surfaces of the first semiconductor element 1 and the second semiconductor element 2 of FIG. 15, the positions of the first dummy pattern 3 and the second dummy pattern 4 will be described. The first semiconductor element 1 is electrically connected to the first circuit element included in the first semiconductor element 1 in addition to the first dummy pattern 3.

In the schematic diagram of FIG. 15, the first dummy pattern 3 and the second dummy pattern 4 are preferably provided on the outer-circumference side of the first semiconductor element 1 and the second semiconductor element 2, and provided in the vicinity of corners. The first dummy pattern 3 and the second dummy pattern 4 may be provided on the center side of the first semiconductor element 1 and the second semiconductor element 2.

The first semiconductor element 1 has at least one first dummy pattern 3. When two or more first dummy patterns 3 are provided in the first semiconductor element 1, the first dummy patterns 3 may have the same pattern shape, or the first dummy patterns 3 may have different pattern shapes. The first dummy patterns 3 are preferably provided at positions facing a second dummy pattern 4.

The second semiconductor element 2 has at least one second dummy pattern 4. When two or more second dummy patterns 4 are provided in the second semiconductor element 2, the second dummy patterns 4 may have the same pattern shape or different pattern shapes.

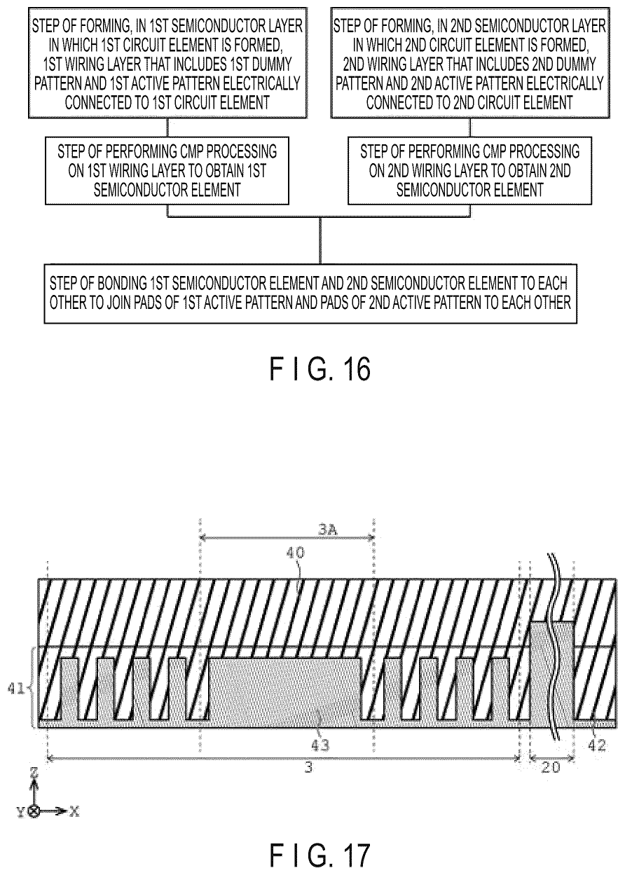

Next, a manufacturing method of the semiconductor device 100 will be described. FIG. 16 illustrates a flowchart of a manufacturing method of a semiconductor device 100. The manufacturing method includes the steps of: forming, in the first semiconductor layer in which the first circuit element is formed, a first wiring layer that includes the first dummy pattern 3 and the first active pattern 20 electrically connected to the first circuit element; performing CMP processing on the first wiring layer to obtain a first semiconductor element; forming, in the second semiconductor layer in which the second circuit element is formed, the second wiring layer that includes the second dummy pattern 4 and the second active pattern 21 electrically connected to the second circuit element; performing CMP processing on the second wiring layer to obtain the second semiconductor element 2; and bonding the first semiconductor element 1 and the second semiconductor element 2 to each other to join the pads of the first active pattern 20 and the pads of the second active pattern 21 to each other.

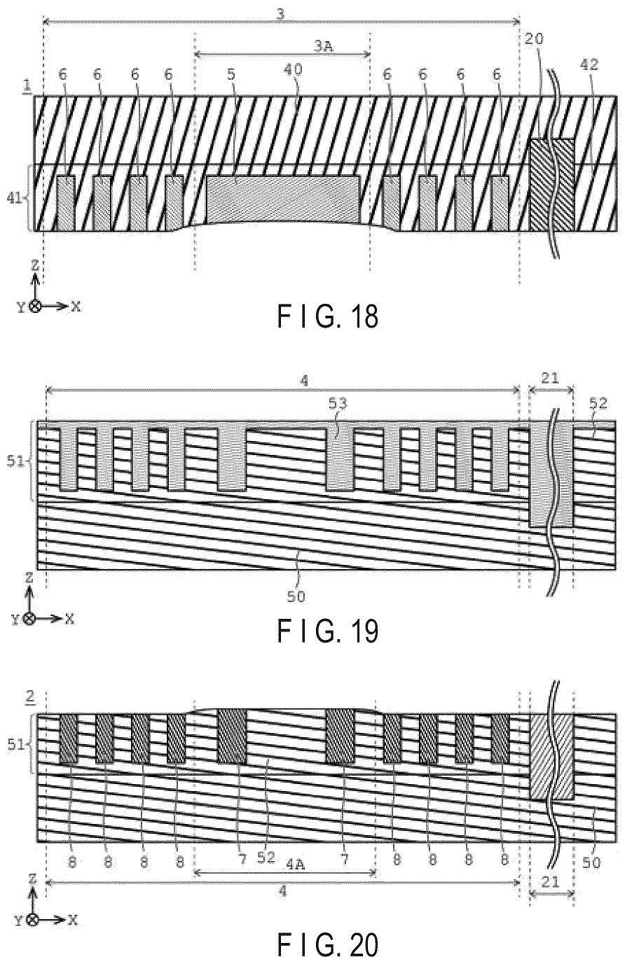

Referring to the schematic diagrams of FIG. 17 to FIG. 21, a manufacturing method of the semiconductor device 100 will be described.

Referring to FIG. 17, a description will be given of a step of forming a first wiring layer 41 that includes the first dummy pattern 3 and the first active pattern 20 electrically connected to the first circuit element. The first wiring layer 41 is in a first semiconductor layer 40 in which the first circuit element is formed. The schematic diagrams of FIG. 17 and the like primarily illustrate the first dummy pattern 3 or the second dummy pattern 4. A first insulating layer 42 (e.g., SiO₂) is also formed in the first semiconductor layer 40, and a first electrode layer 43 of the first dummy pattern 3 and the first active pattern 20 is formed in an opening to obtain a structure in which the first wiring layer 41 is formed. The first electrode layer 43 may be provided to a depth reaching the first semiconductor layer 40.

Next, referring to FIG. 18, a description will be given of a step of performing CMP processing on the first wiring layer to obtain the first semiconductor element 1. The first electrode layer 43 in the schematic diagram of FIG. 17 is polished by CMP until the surface of the first insulating layer 42 is scraped off to obtain the structure illustrated in the schematic diagram of FIG. 18. Since a pad with a high pattern coverage rate is provided in the portion of first region 3A, the portion of the first region 3A will be a concave (recessed) surface with respect to the other surfaces, for example, the surface of the first active pattern 20.

Referring to FIG. 19, a description will be given of a step of forming a second wiring layer 51 that includes the second dummy pattern 4 and the second active pattern 21 electrically connected to the second circuit element. A second insulating layer 52 (e.g., SiO₂) is formed in the second semiconductor layer 50 in which the second circuit element is formed, and a second electrode layer 53 of the second dummy pattern 4 and the second active pattern 21 is formed in an opening to obtain a structure in which the second wiring layer 51 is formed in the second semiconductor layer 50. The second electrode layer 53 may be provided to a depth reaching the second semiconductor layer 50.

Next, referring to FIG. 20, a description will be given of a step of performing CMP processing on the second wiring layer to obtain the second semiconductor element 2. The second electrode layer 53 in the schematic diagram of FIG. 19 is polished by CMP until the surface of the second insulating layer 52 is scraped off to obtain the structure illustrated in the schematic diagram of FIG. 20. Since a pad with a high pattern coverage rate is provided in the portion of second region 4A, the portion of the second region 4A is a convex (protruding) surface with respect to the other surfaces, for example, the surface of the second active pattern 21.

Next, referring to FIG. 21, a description will be given of a step of bonding the first semiconductor element 1 and the second semiconductor element 2 to each other to join the pads of the first active pattern 20 and the pads of the second active pattern 21 to each other. The first semiconductor element 1 illustrated in the schematic diagram of FIG. 18 and the second semiconductor element 2 in the schematic diagram of FIG. 20 are bonded to each other. The respective pads of the first active pattern 20 and the second active pattern 21 are directly joined to each other without solder or the like. Since the first semiconductor element 1 and the second semiconductor element 2 are joined to each other such that the concave surface of the first region 3A and the convex surface of the second region 4A face each other, the first dummy pattern 3 and the second dummy pattern 4 are prevented from inhibiting the joining of the first active pattern 20 and the second active pattern 21.

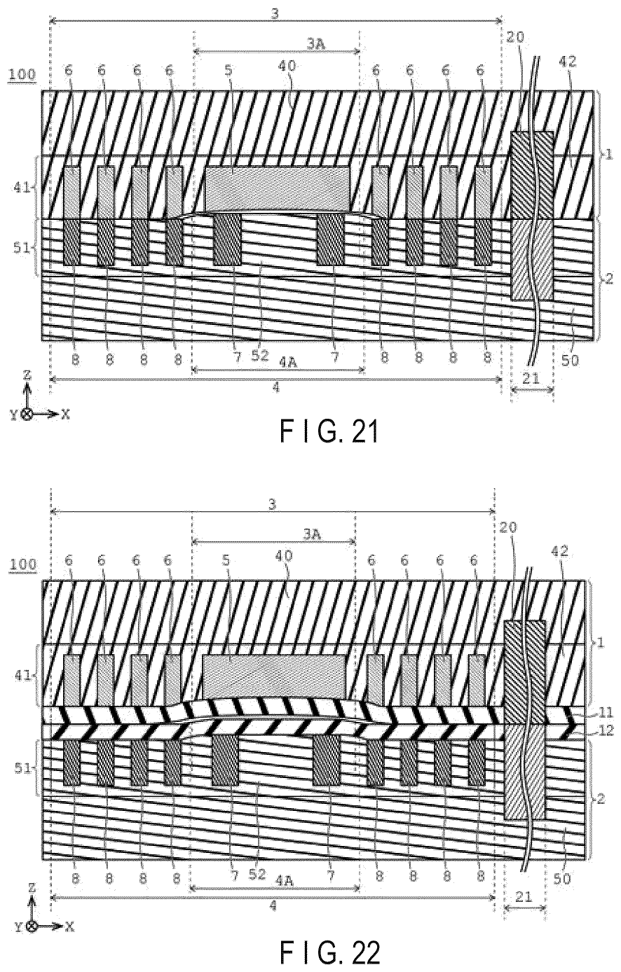

It should be noted that, before the step of bonding the first semiconductor element 1 and the second semiconductor element 2 to each other (to join the pads of the first active pattern 20 and the pads of the second active pattern 21 to each other), the first insulating film 11 can be provided on the surface in which the first dummy pattern 3 of the first semiconductor element 1 is provided, the second insulating film 12 can be provided on the surface in which the second dummy pattern 4 of the second semiconductor element 2, and thereafter the first semiconductor element 1 and the second semiconductor element 2 can be bonded to each other to obtain the semiconductor device 100 illustrated in the schematic cross-sectional view of FIG. 22.

### Second Embodiment

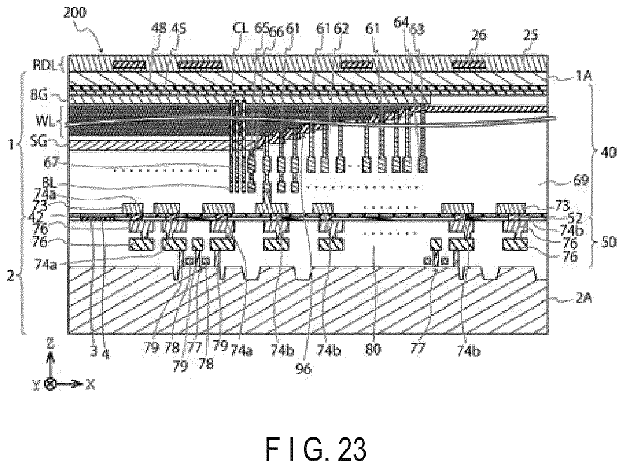

A second embodiment relates to a semiconductor device. A schematic cross-sectional view of a semiconductor device 200 is illustrated in FIG. 23. The schematic cross-sectional view of FIG. 23 illustrates a partial region of the semiconductor device 200. The semiconductor device 200 is a specific example of a semiconductor device 100. The semiconductor storage device 200 may be referred to as a storage device. The semiconductor device 200 includes the first semiconductor element 1, the second semiconductor element 2, and a rewiring layer RDL. Although the configuration of the semiconductor device 200 will be described, embodiments are not limited to a storage device. The semiconductor device 100 may be another type of device.

The first semiconductor element 1 includes a first substrate 1A and the first semiconductor layer 40. The first semiconductor layer 40 is provided on a surface of the first substrate 1A facing the second semiconductor layer 50 side. The first semiconductor element 1 may be obtained by dicing a first wafer. The first substrate 1A is, for example, a silicon (Si) substrate. The first semiconductor layer 40 includes a memory cell array including a plurality of memory cells. A stair structure portion 96 of electrode layers WL is formed at an end (edge) of a memory cell array region in which memory cells are arranged.

The second semiconductor element 2 includes a second substrate 2A and the second semiconductor layer 50. The second semiconductor layer 50 is formed on a circuit formation surface (a surface facing the first semiconductor layer 40 side) of the second substrate 2A. The second semiconductor element 2 may be obtained by dicing a second wafer. The second substrate 2A is, for example, a silicon (Si) substrate. The second semiconductor layer 50 includes therein a control circuit that controls reading, writing, and erasing of memory cells. The memory cell array includes a plurality of memory strings. The memory cell array comprises a stacked body in which a plurality of electrode layers WL and insulating layers are alternately stacked one by one. This stacked body is provided on a backgate BG as a gate layer. It should be noted that the number of the electrode layers WL illustrated is an example, and the number of the electrode layers WL can be freely selected.

The backgate BG and the electrode layers WL are layers that comprise silicon as a main component. Furthermore, the backgate BG and the electrode layers WL contain, for example, boron as an impurity for imparting conductivity to a silicon layer. In addition, the electrode layers WL may contain or comprise a metal silicide.

One memory string is formed into, for example, a U-shape so as to include a pair of columnar portions CL extending in the stacking direction of the electrode layers WL, and a connecting portion connecting respective end portions of the pair of columnar portions CL. The columnar portion CL is formed into, for example, a cylinder or elliptical cylinder shape, penetrates the stacked body, and reaches the backgate BG.

A drain side select gate is provided to an upper end portion of one of the pair of columnar portions CL in the U-shaped memory string, and a source side select gate is provided to an upper end portion of the other. The drain side select gate and the source side select gate are provided on the uppermost electrode layer WL via an interlayer insulating layer.

In the stair structure portion 96, the end portions of the respective electrode layers WL in the X direction are formed into step shapes. A plurality of contact plugs 61 connected to the respective electrode layers WL formed into the step shapes are provided in the stair structure portion 96. The contact plugs 61 penetrate the interlayer insulating layer 69 to be connected to the respective step-shaped electrode layers WL.

In addition, the backgate BG is connected to a contact plug 63 in the stair structure portion 96. A select gate SG (a drain side select gate, a source side select gate) is connected to a contact plug 65.

The contact plugs 61 connected to the electrode layers WL are connected to a word wiring layer 62. The contact plug 63 connected to the backgate BG is connected to a backgate wiring layer 64. The contact plug 65 connected to the select gate SG is connected to a select gate wiring layer 66.

The word wiring layer 62, the backgate wiring layer 64, and the select gate wiring layer 66 are provided in the same layer. In addition, a source line is also provided in the same layer as the word wiring layer 62, the backgate wiring layer 64, and the select gate wiring layer 66.

The word wiring layer 62, the backgate wiring layer 64, the select gate wiring layer 66, and the source line SL are formed by patterning of the same material layer (for example, a metal layer). Therefore, the word wiring layer 62, the backgate wiring layer 64, the select gate wiring layer 66, and the source line SL are simultaneously formed in the same layer with the same material and to the same thickness.

The word wiring layer 62 is further connected, via other plugs and wiring layers, to a surface wiring layer 73 formed on the bonding surface side of the first semiconductor layer 40 with the second semiconductor layer 50.

The backgate wiring layer 64, the select gate wiring layer 66, and the source line SL are also connected to the surface wiring layer 73 via other plugs and wiring layers.

In addition, channel bodies of the columnar portions CL and bit lines BL are connected via plugs 67, and the bit lines BL are further connected to the surface wiring layer 73 via other plugs and wiring layers.

The first semiconductor element 1 includes a memory side wiring layer for electrically connecting the memory cell array to the second semiconductor element 2, and the memory side wiring layer is formed as multilayer wiring including the aforementioned word wiring layer 62, backgate wiring layer 64, select gate wiring layer 66, surface wiring layer 73, and the like.

The surface wiring layer 73 is connected to a circuit side wiring layer 76 of the second semiconductor element 2 via joining metals 74a and 74b. The second semiconductor element 2 includes the second substrate 2A. The second substrate 2A is, for example, a silicon substrate.

The control circuit of the second semiconductor layer 50 is formed as a semiconductor integrated circuit including a transistor 77. The transistor 77 has a MOSFET (metal-oxide-semiconductor field effect transistor) structure that includes, for example, a gate electrode 78, source/drain regions, and the like. The source/drain regions of the MOSFET are connected to the circuit side wiring layer 76 via plugs 79.

The circuit side wiring layer 76 is formed as multilayer wiring on the circuit formation surface via an interlayer insulating layer 80.

The joining metals 74a and 74b are provided between the surface wiring layer 73 of the first semiconductor layer 40 and the wiring layer 76 closest to the first semiconductor layer 40 among the circuit side wiring layers 76 of the second semiconductor layer 50. The joining metals 74a and 74b are, for example, copper or a copper alloy. The joining metals 74a and 74b are formed when a first wafer and a second wafer are bonded to each other, and then annealed. Before bonding of the wafers, the first wafer and the second wafer can be provided with the precursors for each of the first insulating layer 42, the second insulating layer 52, and the joining metals 74a and 74b.

The surface wiring layer 73 of the first semiconductor layer 40 and the uppermost circuit side wiring layer 76 of the second semiconductor layer 50 are joined to the joining metals 74a and 74b. The first insulating layer 42 and the second insulating layer 52 are provided around the joining metals 74a and 74b between the first semiconductor layer 40 and the second semiconductor layer 50. The first insulating layer 42 and the second insulating layer 52 are inorganic films subjected to, for example, CMP polishing.

The first semiconductor element 1 and the second semiconductor element 2 are bonded to each other via the joining metals 74a and 74b, the first insulating layer 42, and the second insulating layer 52. The memory side wiring layer 73 of the first semiconductor layer 40 and the circuit side wiring layer 76 of the second semiconductor layer 50 are electrically connected via the joining metals 74a and 74b.

Therefore, the memory cell array is connected to the control circuit of the second semiconductor layer 50 via the memory side wiring layer 73, the joining metals 74a and 74b, and the circuit side wiring layer 76.

In addition, according to the embodiment, the rewiring layer RDL including an insulating film 25 and a wiring layer 26 is provided on the first substrate 1A side. The rewiring layer RDL is electrically connected to the first semiconductor layer 40 or/and the second semiconductor layer. The wiring layer 26 includes, on the surface side of the semiconductor device 100, a pad that can be electrically connected to the outside. For example, the rewiring layer RDL is connected to the first semiconductor layer 40 or/and the second semiconductor layer via a through electrode that penetrates the first substrate 1A.

The plurality of joining metals 74a and 74b are arranged in the joining portion between the first semiconductor layer 40 and the second semiconductor layer 50. The plurality of joining metals 74a and 74b mainly include a plurality of bit line lead-out portions 74a electrically connected to the bit lines BL, and a plurality of word line lead-out portions 74b electrically connected to the electrode layers WL.

The bit line lead-out portions 74a are arranged in a region overlapping, in the stacking direction, the memory cell array region in which the plurality of memory strings are arranged.

The word line lead-out portions 74b are arranged in a region overlapping, in the stacking direction, with the region in which the stair structure portion 96 and the like are formed and that is on the outer side of the memory cell array region. In FIG. 23, the plurality of word line lead-out portions 74b are arranged in a region below the stair structure portion 96 and a region to the lower right of the stair structure portion 96.

The joining metals (bit line lead-out portions) 74a and the joining metals (word line lead-out portions) 74b are metals formed by joining the first active pattern 20 and the second active pattern 21 joined to each other.

The first dummy pattern 3 is electrically insulated from the first circuit element formed in the first semiconductor layer 40, and is joined to the second dummy pattern 4 electrically insulated from the second circuit element formed in the second semiconductor layer 50.

Hereinafter, certain technical proposals are described. Such proposals are provided for purposes of a fuller disclosure of certain embodiments but are not themselves claims nor in any manner limiting of the present disclosure.

### Technical Proposal 1

A semiconductor device including:
a first semiconductor element that includes, in a surface, a first dummy pattern and a first active pattern; and
a second semiconductor element that includes, in a surface, a second dummy pattern facing the first dummy pattern, and that is joined to the first semiconductor element, wherein
the first dummy pattern includes a first region,
the second dummy pattern includes a second region,
the first region and the second region face each other,
a size of the first region is larger than an average area of pads included in the first active pattern, and
a pattern coverage rate of the first region is different from a pattern coverage rate of the second region.

### Technical Proposal 2

The semiconductor device of Technical Proposal 1, wherein the pattern coverage rate of the second region is 0% or more and 80% or less of the pattern coverage rate of the first region.

### Technical Proposal 3

The semiconductor device of Technical Proposal 1 or 2, wherein the pattern coverage rate of the second region is 0% or more and 20% or less of the pattern coverage rate of the first region.

### Technical Proposal 4

The semiconductor device of any one of Technical Proposals 1 to 3, wherein the pattern coverage rate of the first region is higher than the pattern coverage rate of the second region,
the pattern coverage rate of the first region is 20% or more and 100% or less, and
the pattern coverage rate of the second region is 0% or more and 50% or less.

### Technical Proposal 5

The semiconductor device of any one of Technical Proposals 1 to 4, wherein the pattern coverage rate of the first region is higher than the pattern coverage rate of the entire first dummy pattern, and
the pattern coverage rate of the second region is lower than the pattern coverage rate of the entire second dummy pattern.

### Technical Proposal 6

The semiconductor device of any one of Technical Proposals 1 to 5, wherein the first region is a concave surface, and
the second region is a convex surface.

### Technical Proposal 7

The semiconductor device of any one of Technical Proposals 1 to 6, wherein the first region is a concave surface,
the second region is a convex surface, and
the convex surface facing the concave surface enters a gap of the concave surface.

### Technical Proposal 8

The semiconductor device of Technical Proposal 6 or 7, wherein a first insulating film is provided on the first dummy pattern,
a second insulating film is provided on the second dummy pattern,
a concave surface corresponding to the first region is present in the first insulating film on the first dummy pattern,
a convex surface corresponding to the second region is present in the second insulating film on the second dummy pattern, and
the convex surface of the second insulating film facing the concave surface of the first insulating film enters a gap of the concave surface of the first insulating film.

### Technical Proposal 9

The semiconductor device of any one of Technical Proposals 1 to 8, wherein the first dummy pattern is not electrically connected to a circuit element in the first semiconductor element, and
the second dummy pattern is not electrically connected to a circuit element in the second semiconductor element.

### Technical Proposal 10

The semiconductor device of any one of Technical Proposals 1 to 9, wherein, in the first region, a pad of a solid film is arranged or pads are arranged at high density, and
in the second region, a pad is not arranged or pads are arranged at lower density than in the first region.

### Technical Proposal 11

The semiconductor device of any one of Technical Proposals 1 to 10, wherein a pad is arranged in the first region,
a pad is arranged in the second region, and
the pad in the first region and a part of the pad in the second region are joined to each other.

### Technical Proposal 12

The semiconductor device of any one of Technical Proposals 1 to 11, wherein a third region with a low pattern coverage rate is included outside the first region,
a fourth region with a high pattern coverage rate is included outside the second region, and
the third region and the fourth region face each other.

### Technical Proposal 13

The semiconductor device of any one of Technical Proposals 1 to 12, wherein a pad is arranged in the third region,
a pad is arranged in the fourth region, and
the pad in the third region and a part of the pad in the fourth region are joined to each other.

### Technical Proposal 14

A manufacturing method of a semiconductor device, the manufacturing method including the steps of:
forming, in a first semiconductor layer in which a first circuit element is formed, a first wiring layer that includes a first dummy pattern and a first active pattern electrically connected to the first circuit element;
performing CMP processing on the first wiring layer to obtain a first semiconductor element;
forming, in a second semiconductor layer in which a second circuit element is formed, a second wiring layer that includes a second dummy pattern and a second active pattern electrically connected to the second circuit element;
performing CMP processing on the second wiring layer to obtain a second semiconductor element; and
bonding the first semiconductor element and the second semiconductor element to each other to join pads of the first active pattern and pads of the second active pattern to each other, wherein
a first region included in the first dummy pattern and a second region included in the second dummy pattern face each other,
a size of the first region is larger than an average area of the pads included in the first active pattern, and
a pattern coverage rate of the first region is different from a pattern coverage rate of the second region.

### Technical Proposal 15

The manufacturing method of a semiconductor device of Technical Proposal 14, wherein the first region is a concave surface with respect to a surface of the first active pattern,
the second region is a convex surface with respect to a surface of the second active pattern, and
the concave surface of the first region and the convex surface of the second region face each other.

### Technical Proposal 16

The manufacturing method of a semiconductor device of Technical Proposal 14 or 15, wherein the pattern coverage rate of the second region is 0% or more and 80% or less of the pattern coverage rate of the first region.

### Technical Proposal 17

The manufacturing method of a semiconductor device of any one of Technical Proposals 14 to 16, wherein the pattern coverage rate of the second region is 0% or more and 20% or less of the pattern coverage rate of the first region.

### Technical Proposal 18

The manufacturing method of a semiconductor device of any one of Technical Proposals 14 to 17, wherein the pattern coverage rate of the first region is 20% or more and 100% or less, and
the pattern coverage rate of the second region is 0% or more and 50% or less.

### Technical Proposal 19

The manufacturing method of a semiconductor device of any one of Technical Proposals 14 to 18, wherein the pattern coverage rate of the first region is higher than the pattern coverage rate of the entire first dummy pattern, and
the pattern coverage rate of the second region is lower than the pattern coverage rate of the entire second dummy pattern.

### Technical Proposal 20

The manufacturing method of a semiconductor device of any one of Technical Proposals 14 to 19, wherein a third region with a low pattern coverage rate is included outside the first region,
a fourth region with a high pattern coverage rate is included outside the second region, and
the third region and the fourth region face each other.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is

1. A semiconductor device, comprising:
a first semiconductor element with a first dummy pattern and a first active pattern; and
a second semiconductor element joined to a surface of the first semiconductor element, the second semiconductor element having a second dummy pattern facing the first dummy pattern, wherein
the first dummy pattern includes a first region,
the second dummy pattern includes a second region,
the first region and the second region face each other,
a size of the first region is larger than an average area of pads included in the first active pattern, and
a pattern coverage rate of the first region is different from a pattern coverage rate of the second region.

2. The semiconductor device of claim 1, wherein the pattern coverage rate of the second region is 80% or less of the pattern coverage rate of the first region.

3. The semiconductor device of claim 1, wherein the pattern coverage rate of the second region is 20% or less of the pattern coverage rate of the first region.

4. The semiconductor device of claim 1, wherein
the pattern coverage rate of the first region is greater than the pattern coverage rate of the second region,
the pattern coverage rate of the first region is 20% to 100%, and
the pattern coverage rate of the second region is 50% or less.

5. The semiconductor device of claim 1, wherein
the pattern coverage rate of the first region is greater than an overall pattern coverage rate of the first dummy pattern, and
the pattern coverage rate of the second region is less than an overall pattern coverage rate of the second dummy pattern.

6. The semiconductor device of claim 1, wherein
the first region is a concave surface, and
the second region is a convex surface.

7. The semiconductor device of claim 6, wherein
a first insulating film is on the first dummy pattern,
a second insulating film is on the second dummy pattern,
a concave surface corresponding to the first region is present in the first insulating film on the first dummy pattern,
a convex surface corresponding to the second region is present in the second insulating film on the second dummy pattern, and
the convex surface of the second insulating film facing the concave surface of the first insulating film enters a gap formed by the concave surface of the first insulating film.

8. The semiconductor device of claim 1, wherein
the first region has a concave surface,
the second region has a convex surface, and
the convex surface of the second region enters a gap formed by the concave surface of the first region.

9. The semiconductor device of claim 1, wherein
the first dummy pattern is not electrically connected to any circuit element in the first semiconductor element, and
the second dummy pattern is not electrically connected to any circuit element in the second semiconductor element.

10. The semiconductor device of claim 1, wherein
in the first region, a pad of a solid film is present or pads are present at high density, and
in the second region, no pad is present or pads are present at lower density than in the first region.

11. The semiconductor device of claim 1, wherein
a pad is in the first region,
a pad is in the second region, and
the pad in the first region and a part of the pad in the second region are joined to each other.

12. The semiconductor device of claim 1, wherein
a third region with a low pattern coverage rate is outside the first region in the first dummy pattern,
a fourth region with a high pattern coverage rate is outside the second region in the second dummy pattern, and
the third region and the fourth region face each other.

13. The semiconductor device of claim 12, wherein
a pad is in the third region,
a pad is in the fourth region, and
the pad in the third region and a part of the pad in the fourth region are joined to each other.

14. A manufacturing method for a semiconductor device, the manufacturing method comprising:
forming, in a first semiconductor layer in which a first circuit element is formed, a first wiring layer that includes a first dummy pattern and a first active pattern electrically connected to the first circuit element;
performing chemical mechanical polishing processing on the first wiring layer to obtain a first semiconductor element;
forming, in a second semiconductor layer in which a second circuit element is formed, a second wiring layer that includes a second dummy pattern and a second active pattern electrically connected to the second circuit element;
performing chemical mechanical polishing processing on the second wiring layer to obtain a second semiconductor element; and
bonding the first semiconductor element and the second semiconductor element to each other to join pads of the first active pattern and pads of the second active pattern to each other, wherein
a first region included in the first dummy pattern and a second region included in the second dummy pattern face each other,
a size of the first region is greater than an average area of the pads included in the first active pattern, and
a pattern coverage rate of the first region is different from a pattern coverage rate of the second region.

15. The manufacturing method of claim 14, wherein
the first region has a concave surface with respect to a surface of the first active pattern,
the second region has a convex surface with respect to a surface of the second active pattern, and
the concave surface of the first region and the convex surface of the second region face each other.

16. The manufacturing method of claim 14, wherein
the pattern coverage rate of the second region is 80% or less of the pattern coverage rate of the first region.

17. The manufacturing method of claim 14, wherein
the pattern coverage rate of the second region is 20% or less of the pattern coverage rate of the first region.

18. The manufacturing method of claim 14, wherein
the pattern coverage rate of the first region is 20% to 100%, and
the pattern coverage rate of the second region is 0% to 50%.

19. The manufacturing method of claim 14, wherein
the pattern coverage rate of the first region is greater than an overall pattern coverage rate of the first dummy pattern, and
the pattern coverage rate of the second region is less than an overall pattern coverage rate of the second dummy pattern.

20. The manufacturing method of claim 14, wherein
a third region with a low pattern coverage rate is outside the first region in the first dummy pattern,
a fourth region with a high pattern coverage rate is outside the second region in the second dummy pattern, and
the third region and the fourth region face each other.
